(19) United States
(12) Patent Application Publication
(10) Pub. No.: US 2010/0326497 A1
(43) Pub. Date: Dec. 30, 2010

(54) HIGHLY EFFICIENT TANDEM POLYMER PHOTOVOLTAIC CELLS

(75) Inventors: Yang Yang, Los Angeles, CA (US); Yue Wu, San Gabriel, CA (US); Zirou Hong, Los Angeles, CA (US); Mi-Hyae Park, Los Angeles, CA (US); Srinivas Sista, Los Angeles, CA (US)

Correspondence Address: VENABLE LLP, P.O. BOX 34385, WASHINGTON, DC, 20043-9998, US

(73) Assignees: The Regents of the University of California, Oakland, CA (US); SOLARMER ENERGY, INC., El Monte, CA (US)

(21) Appl. No.: 12/826,344

(22) Filed: Jun. 29, 2010

Related U.S. Application Data
(60) Provisional application No. 61/221,404, filed on Jun. 29, 2009.

(51) Int. Cl. H01L 31/06; H01L 51/48; H01L 31/18

(52) U.S. Cl. 136/249; 438/82; 257/E51.026; 257/E51.017

(57) ABSTRACT

A tandem polymer photovoltaic device includes a first bulk hetero-junction polymer semiconductor layer, a second bulk hetero-junction polymer semiconductor layer spaced apart from the first bulk hetero-junction polymer semiconductor layer, and a metal-semiconductor layer between and in contact with the first and second bulk hetero junction polymer semiconductor layers. The first and second bulk hetero-junction polymer semiconductor layers have complementary photon absorption spectra.

### CROSS REFERENCE TO RELATED APPLICATIONS AND FEDERAL FUNDING

This application claims priority to U.S. Provisional Application No. 61/221,404, filed Jun. 29, 2009, the entire contents of which are incorporated herein by reference.

This invention was made with Government support of Grant No. N00014-04-1-0434, awarded by the Office of Naval Research and Grant No. FA9550-07-1-0264, awarded by the Air Force Office of Scientific Research. The Government has certain rights in this invention.

### BACKGROUND

1. Field of Invention

Embodiments of this invention relate to photovoltaic cells and methods of producing photovoltaic cells, and more particularly to highly efficient tandem polymer photovoltaic cells and methods of production.

2. Discussion of Related Art

The contents of all references referred to herein, including articles, published patent applications and patents are hereby incorporated by reference.

Photovoltaic (PV) cells, also known as solar cells, generate electrical power from incident light. The term “light” is used broadly herein to refer to electromagnetic radiation which may include visible, ultraviolet and infrared light. Traditionally, PV cells have been constructed of a number of inorganic semiconductors, e.g., crystalline, polycrystalline and amorphous silicon, gallium arsenide, cadmium telluride and others. More recently, PV cells have been constructed using organic materials.

Solar cells are characterized by the efficiency with which they can convert incident solar power to useful electric power. Devices utilizing crystalline or amorphous silicon dominate commercial applications, and some have achieved efficiencies of 23% or greater. However, efficient crystalline-based devices, especially of large surface area, are difficult and expensive to produce due to the problems inherent in producing large crystals without significant efficiency-degrading defects. On the other hand, high efficiency amorphous silicon devices still suffer from problems with stability. Present commercially available amorphous silicon cells have stabilized efficiencies between 4 and 8%. More recent efforts have focused on the use of organic photovoltaic cells to achieve acceptable photovoltaic conversion efficiencies with economical production costs as well as other possible advantageous properties.

PV devices produce a photo-generated voltage when they are connected across a load and are irradiated by light. When irradiated without any external electronic load, a PV device generates its maximum possible voltage, V open-circuit, or V_{OC}. If a PV device is irradiated with its electrical contacts shorted, a maximum short-circuit current, or I_{SC}, is produced. (Current is conventionally referred to as “I” or “J”.) When actually used to generate power, a PV device is connected to a finite resistive load in which the power output is given by the product of the current and voltage, I×V. The maximum total power generated by a PV device is inherently incapable of exceeding the product I_{SC}×V_{OC}. When the load value is optimized for maximum power extraction, the current and voltage have values, Iₘₐₓ and Vₘₐₓ, respectively. A figure of merit for solar cells is the fill factor, ff (or FF), defined as:

$$ff = \frac{{I}_{max} {V}_{max}}{{I}_{SC} {V}_{OC}}$$

where ff is always less than 1, as I_{SC} and V_{OC} are never achieved simultaneously in actual use. Nonetheless, as ff approaches 1, the device is more efficient.

When electromagnetic radiation of an appropriate energy is incident upon a semiconductive organic material, for example, an organic molecular crystal (OMC) material, or a polymer, a photon can be absorbed to produce an excited molecular state. This energy absorption is associated with the promotion of an electron from a bound state in the highest occupied molecular orbital (HOMO) to the lowest unoccupied molecular orbital (LUMO), or equivalently, the promotion of a hole from the LUMO to the HOMO. In organic thin-film photoconductors, the generated excited state is believed to be an exciton, i.e., an electron-hole pair in a bound state which is transported as a quasi-particle. The excitons can have an appreciable life-time before recombination. To produce a photocurrent the electron-hole pair must become separated, for example at a donor-acceptor interface between two dissimilar contacting organic thin films. The interface of these two materials is called a photovoltaic heterojunction If the charges do not separate, they can recombine with each other (known as quenching) either radiatively, by the emission of light of a lower energy than the incident light, or non-radiatively, by the production of heat. Either of these outcomes is undesirable in a PV device. In traditional semiconductor theory, materials for forming PV heterojunctions have been denoted as generally being of either n (donor) type or p (acceptor) type. Here n-type denotes that the majority carrier type is the electron. This could be viewed as the material having many electrons in relatively free energy states. The p-type denotes that the majority carrier type is the hole. Such material has many holes in relatively free energy states. The type of the background majority carrier concentration depends primarily on unintentional doping by defects or impurities. The type and concentration of impurities determine the value of the Fermi energy, or level, within the gap between the highest occupied molecular orbital (HOMO) and the lowest unoccupied molecular orbital (LUMO), called the HOMO-LUMO gap. The Fermi energy characterizes the statistical occupation of molecular quantum energy states denoted by the value of energy for which the probability of occupation is equal to ½. A Fermi energy near the LUMO energy indicates that electrons are the predominant carrier. A Fermi energy near the HOMO energy indicates that holes are the predominant carrier. Accordingly, the Fermi energy is a primary characterizing property of traditional semiconductors and the PV heterojunction has traditionally been the p-n interface.

A significant property in organic semiconductors is carrier mobility. Mobility measures the ease with which a charge carrier can move through a conducting material in response to an electric field. As opposed to free carrier concentrations, carrier mobility is determined in large part by intrinsic properties of the organic material such as crystal symmetry and periodicity. Appropriate symmetry and periodicity can produce higher quantum wavefunction overlap of HOMO levels producing higher hole mobility, or similarly, higher overlap of LUMO levels to produce higher electron mobility. Moreover, the donor or acceptor nature of an organic semiconductor may be at odds with the higher carrier mobility. The result is that device configuration predictions from donor/acceptor criteria may not be borne out by actual device performance. Due to these electronic properties of organic materials, the nomenclature of “hole-transporting-layer” (HTL) or “electron-transporting-layer” (ETL) is often used rather than designating them as “p-type” or “acceptor-type” and “n-type” or “donor-type”. In this designation scheme, an ETL will be preferentially electron conducting and an HTL will be preferentially hole transporting. However, we will use the terms p-type and n-type, for convenience.

Polymer tandem PV cells have spurred much interest because of their ability to harvest a greater portion of the solar spectrum. However, the function of the interlayer that joins the two sub-cells in a tandem cell has not been well understood even though it is important in achieving high efficiency. Organic solar cells have attracted much attention in the past decade, mainly due to their potential as a candidate for next generation of renewable energy resources (C. W. Tang, Appl. Phys. Lett. 1986, 48, 183; H. Hiramoto, H. Fujiwara, M. Yokoyama, Appl. Phys. Lett. 1991, 58, 1062; N. S. Sariciftci, D. Braun, C. Zhang, V. I. Srdanov, A. J. Heeger, G. Stucky, F. Wudl, Appl. Phys. Lett. 1993, 62, 585). Significant improvement in polymer photovoltaic cells has been achieved recently with the synthesis of new donor polymers that can reach PCE higher than 5% when blended with methanofullerene (PCBM) (F. Padinger, R. S. Rittberger, N. S. Sariciftci, Adv. Funct. Mater. 2003, 13, 85; G. Li, V. Shrotriya, J. Huang, Y. Yao, T. Moriarty, K. Emery, Y. Yang, Nat. Mater. 2005, 4, 864; M. S. White, D. C. Olson, S. E. Shaheen, N. Kopidakis, D. S. Ginley, Appl. Phys. Lett. 2006, 89, 143517; J. Peet, J. Y. Kim, N. E. Coates, W. L. Ma, D. Moses, A. J. Heeger, G. C. Bazan, Nat. Mater. 2007, 6, 497; J. H. Hou, H.-Y. Chen, S. Zhang, G. Li, Y. Yang, J. Am. Chem. Soc. 2008, 130, 16144; Y. Liang, Y. Wu, D. Feng, S.-T. Tsai, H.-J. Son, G. Li, L. Yu, J. Am. Chem. Soc. 2009, 131, 56; S. H. Park, A. Roy, S. Beaupré, S Cho, N. Coates, J. S. Moon, D. Moses, M. Leclerc, K. Lee, A. J. Heeger, Nat. Photonics 2009, 3, 297). However, narrow absorption ranges of the donor polymers leaves major portions of the solar spectrum unused. To achieve broad absorption, tandem structures have been employed by stacking two or more bulk heterojunction (BHJ) (A. Hadipour, B. de Boer, P. W. M. Blom, J. Appl. Phys. 2007, 102, 074506) PV cells that have complementary absorption spectra. (BHJ PV cells have both p-type and n-type semiconductor materials distributed throughout the bulk of the active layer rather than separate layers of n-type and p-type semiconductors.) For a series connection of two cells, the open circuit voltage (V_{oc} of the tandem cell is the sum of V_{oc} of the two sub-cells, while the overall current is limited by the sub-cell having the smaller current. With this strategy, tremendous efforts have been made to develop desirable device configurations and interlayers through various methods (J. Drechsel, B. Mannig, F. Kozlowski, M. Pfeiffer, M. Leo, H. Hoppe, Appl. Phys. Lett. 2005, 86, 244102; J. Gilot, M. M. Wienk, R. A. J. Janssen, Appl. Phys. Lett. 2007, 90, 143512; M. Hiramoto, M. Suezaki, M. Yokoyama, Chem. Lett. 1990, 327), and tandem cells with PCEs over 6% have been achieved (J. Y. Kim, K. Lee, N. E. Coates, D. Moses, T.-Q. Nguyen, M. Dante, A. J. Heeger Science 2007, 317, 222). However, since then there has been little major progress made in further improving polymer tandem cells, mainly due to the complicated processing required and the lack of understanding of the working mechanism in such a dual-BHJ system. Consequently, there remains a need for improved tandem polymer photovoltaic devices.

### SUMMARY

A tandem polymer photovoltaic device according to an embodiment of the current invention includes a first bulk hetero-junction polymer semiconductor layer, a second bulk hetero-junction polymer semiconductor layer spaced apart from the first bulk hetero-junction polymer semiconductor layer, and a metal-semiconductor layer between and in contact with the first and second bulk hetero-junction polymer semiconductor layers. The first and second bulk hetero-junction polymer semiconductor layers have complementary photon absorption spectra.

A method of producing a tandem polymer photovoltaic device according to an embodiment of the current invention includes providing a transparent substrate structure comprising a transparent substrate and a transparent electrode, forming a first bulk hetero junction polymer semiconductor layer in electrical connection with the transparent electrode, forming a metal-semiconductor layer in electrical connection with the first bulk hetero-junction polymer semiconductor layer, and forming a second bulk hetero junction polymer semiconductor layer in electrical connection with the metal-semiconductor layer. The first and second bulk hetero junction polymer semiconductor layers have complementary photon absorption spectra.

### BRIEF DESCRIPTION OF THE DRAWINGS

The invention may be better understood by reading the following detailed description with reference to the accompanying figures in which:

FIG. 1 is a schematic illustration of a tandem polymer photovoltaic device according to an embodiment of the current invention;

FIG. 2 is a proposed energy level diagram of the of FIG. 1 with TiO₂/PEDOT4083 as the inter-connection layer;

FIG. 3 shows absorbance (optical density, i.e. O.D.) of P3HT:PC₇₀BM and PSBTBT:PC₇₀BM BHJ films, and tandem photovoltaic cells without a reflective cathode;

FIG. 4 provides a calculated absorption profile of the tandem polymer photovoltaic device under AM1.5G illumination;

FIG. 5 provides J-V characteristics of a tandem polymer photovoltaic device and a reference single cell measured under standard AM1.5G, 100 mW/cm² illumination;

FIG. 6 provides EQE of sub-cells in a tandem polymer photovoltaic device (with and without monocolor light bias) and reference single cells;

FIG. 7 provides dark J-V characteristics of a tandem polymer photovoltaic device and a single cell (ITO/PEDOT/P3HT:PC₇₀BM/UT-Al/TiO₂/PEDOT4083/Al) before and after light illumination;

FIG. 8 provides J-V characteristics of tandem polymer photovoltaic devices and single cells under illumination with and without a 400 nm cutoff filter;

FIG. 9 provides J-V characteristics under illumination of single cells with the structure ITO/PEDOT4083/P3HT:PC₇₀BM/UT-Al/TiO₂/PEDOT:PSS/Al using either PEDOT4083 or highly conductive PH500 to demonstrates some concepts of the current invention; and

FIG. 10 provides results for a tandem polymer photovoltaic device using PH500 as an interlayer before and after defining active area by scratching.

### DETAILED DESCRIPTION

In describing embodiments of the present invention, specific terminology is employed for the sake of clarity. However, the invention is not intended to be limited to the specific terminology so selected. It is to be understood that each specific element includes all technical equivalents which operate in a similar manner to accomplish a similar purpose.

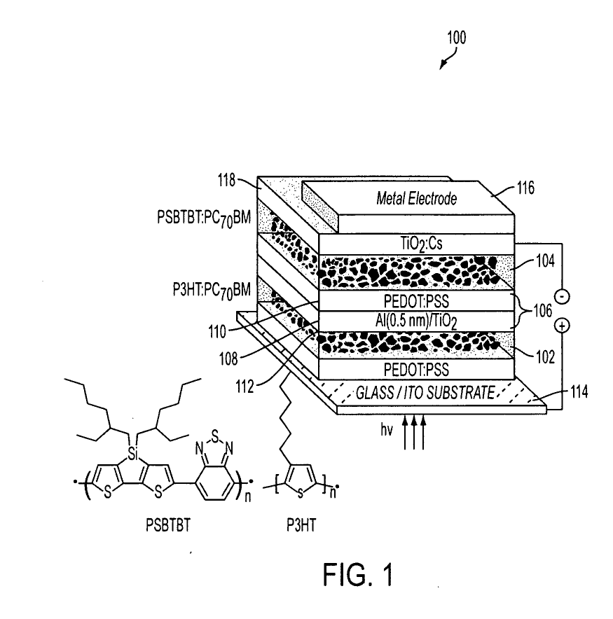

FIG. 1 is a schematic illustration of a tandem polymer photovoltaic device 100 according to an embodiment of the current invention. The tandem polymer photovoltaic device 100 includes a first bulk hetero junction polymer semiconductor layer 102, a second bulk hetero junction polymer semiconductor layer 104 spaced apart from the first bulk hetero junction polymer semiconductor layer 102, and a metal-semiconductor layer 106 between and in contact with the first and second bulk hetero-junction polymer semiconductor layers (102, 104). The first and second bulk hetero-junction polymer semiconductor layers (102, 104) have complementary photon absorption spectra.

The metal-semiconductor layer 106 includes an n-type sub-layer 108 and a p-type sub-layer 110. The n-type sub-layer 108 of the metal-semiconductor layer 106 can include nano-crystalline TiO₂, for example. The p-type sub-layer 110 of the metal-semiconductor layer can include poly(3,4-ethylenedioxythiophene) poly (styrenesulfonate) (PEDOT:PSS), for example. The metal-semiconductor layer 106 can further include a wetting layer in some embodiments between the n-type sub-layer 108 and one of the first and second bulk hetero junction polymer semiconductor layers (102, 104). In some embodiments, the wetting layer can be less than 1 nm thick, for example. In the example of FIG. 1, the wetting layer 112 is a 0.5 nm ultrathin layer of aluminum between the n-type sub-layer 108 and the first bulk hetero-junction polymer semiconductor layer 102.

In some embodiments, the first bulk hetero-junction polymer semiconductor layer 102 can be P3HT:PC₇₀BM and the second bulk hetero junction polymer semiconductor layer 104 can be PSBTBT:PC₇₀BM, for example.

The tandem polymer photovoltaic device 100 also includes a transparent electrode on a transparent substrate 114 in electrical connection with the first bulk hetero-junction polymer semiconductor layer 102 and a metal electrode 116 in electrical connection with the second bulk hetero junction polymer semiconductor layer 104. The tandem polymer photovoltaic device 100 can also include an electron extraction layer 118 between the second bulk hetero junction polymer semiconductor layer 104 and the metal electrode 116.

A method of producing a tandem polymer photovoltaic device according to an embodiment of the current invention includes providing a transparent substrate structure that includes a transparent substrate and a transparent electrode, forming a first bulk hetero-junction polymer semiconductor layer in electrical connection with the transparent electrode, forming a metal-semiconductor layer in electrical connection with the first bulk hetero junction polymer semiconductor layer, and forming a second bulk hetero-junction polymer semiconductor layer in electrical connection with the metal-semiconductor layer. The first and second bulk hetero-junction polymer semiconductor layers have complementary photon absorption spectra. The metal-semiconductor layer can include an n-type sub-layer and a p-type sub-layer. The method can include forming an n-type sub-layer of nano-crystalline TiO₂ by a non-hydrolytic sol-gel process according to an embodiment of the current invention. The p-type sub-layer of the metal-semiconductor layer can be PEDOT:PSS, for example.

We have studied the role of the n-type and p-type layers constituting the metal-semiconductor layer as well as several important issues of the tandem structure, including optical optimization, interfacial engineering and accurate efficiency characterization for some particular applications. Investigation of a metal-semiconductor layer that includes an n-type nanocrystalline TiO₂ layer and a p-type conducting polymer layer revealed that it indeed acts as a metal-semiconductor contact as opposed to a tunnel junction in inorganic tandem cells. By making use of an efficient interlayer, we demonstrated highly efficient tandem cells with power conversion efficiencies (PCE) of 5.84% in one example. In some embodiments, a highly conductive metal-semiconductor layer should be avoided. Further enhancements of the efficiency of tandem cells with large band gap polymers can be expected according to some embodiments of the current invention.

### EXAMPLES

Several criteria that should be considered in order to achieve highly efficient tandem polymer photovoltaic devices include minimal absorption overlap between the two sub-cells, a compatible fabrication process for constructing the layer-by-layer structure, and an efficient interlayer (metal-semiconductor layer) for connecting the sub-cells. The following examples can facilitate an understanding of the physics of an efficient interlayer and the role of n-type TiO₂ and p-type poly(3,4-ethylenedioxythiophene) poly(styrenesulfonate) (PEDOT:PSS) materials. A TiO₂ sublayer was synthesized via a non-hydrolytic sol-gel process, which offers a simple way to control the nanocrystal size and to fabricate the film without thermal-annealing and hydrolysis treatment in air (M.-H. Park, J.-H. Li, A. Kumar, G. Li, Y. Yang, Adv. Funct. Mater. 2009, 19, 1241). On the TiO₂ surface we provided a PEDOT:PSS (VP AI 4083 from H. C. Stark, PEDOT4083) film (conductivity of 10⁻³ Scm⁻¹) that acts as an anode for the rear cell. Utilization of PEDOT4083, instead of highly conductive PEDOT:PSS (PH500), allows accurate evaluation of active areas of photovoltaic cells and thus overall efficiencies, as discussed below in detail.

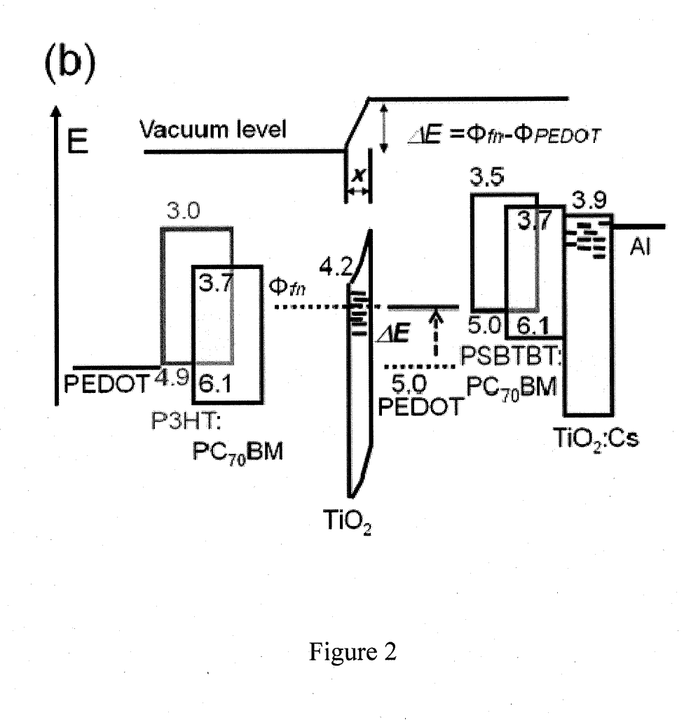

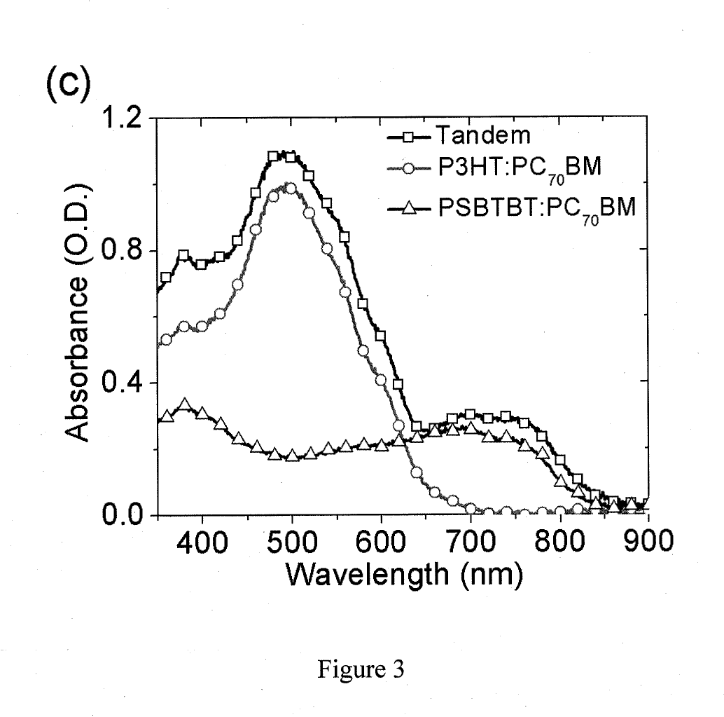

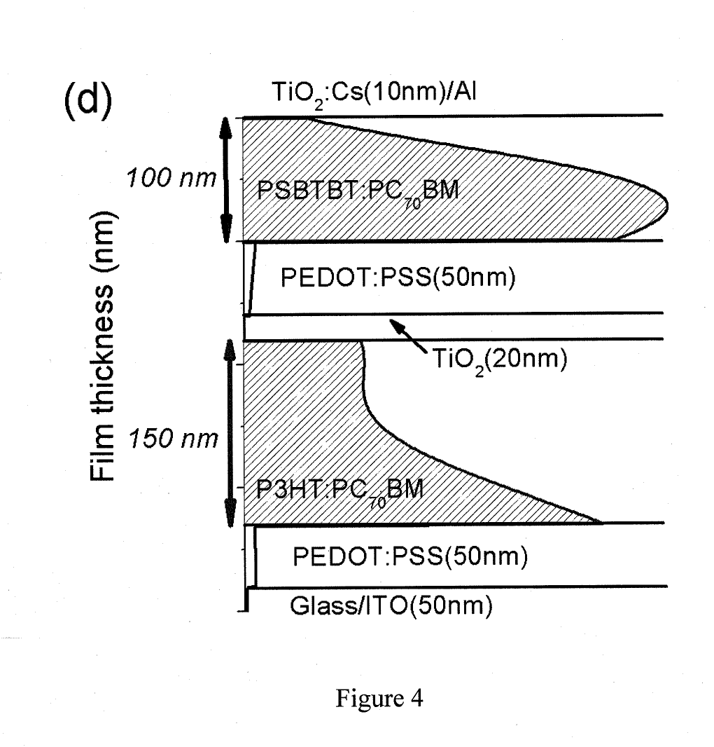

In our tandem structure, poly(3-hexylthiophene) (P3HT) with bandgap of 1.9 eV is used as a front cell. One advantage of P3HT:PC₇₀BM BHJs is that its short circuit current density (J_{sc}) can be easily and precisely tuned by changing thickness, while V_{oc} and the fill factor (FF) remain constant, thereby allowing photocurrent balance between the sub-cells. The rear cell includes a lower band gap (1.5 eV) polymer, poly[(4,4′-bis(2-ethylhexyl)dithieno[3,2-b:2′,3′-d]silole)-2,6-diyl-alt-(2,1,3-benzothiadiazole)-4,7-diyl] (PSBTBT) (J. H. Hou, H.-Y. Chen, S. Zhang, G. Li, Y. Yang, J. Am. Chem. Soc. 2008, 130, 16144). The PCE of a PSBTBT:PC₇₀BM single cell increases by 10% when the incident light is reduced from 1 sun to ½ sun because of reduced non-geminate recombination (see supporting information, SI-[A], FIG. SI-1). (The supporting information can be found in U.S. Provisional Application No. 61/221,404 to which the current application claims priority, the entire contents of which are incorporated herein by reference.) This property of PSBTBT makes it suitable to be used as a rear sub-cell since the light intensity received by the rear sub-cell is attenuated by ˜40% after passing through the front P3HT:PCBM sub-cell. The device configuration and the proposed energy level diagram of the tandem photovoltaic cell are shown in FIGS. 1 and 2, respectively. As shown in FIG. 3, absorbance of the tandem cell without a cathode reaches an optical density over 0.8 in the spectral range 350-600 nm, where the absorption of the two BHJs overlap, whereas the absorbance value reaches 0.3 at 750 nm for the rear cell absorption. This suggests that approximately over 50% of incident light from 650 nm to 790 nm is absorbed in the presence of a reflective cathode. Optical simulation was performed to calculate the absorption profile for matching the absorption of the two sub-cells (see supporting FIG. SI-2 for n, k values derived from Ellipsometry measurement) (D. Sievers, V. Shrotriya, Y. Yang, J. Appl. Phys. 2006, 100, 114509). According to the optical simulation results shown in FIG. 4, a 100 nm PSBTBT:PC₇₀BM film absorbs 15% more photon flux than the front P3HT:PC₇₀BM cell under illumination of AM1.5G. Therefore, the P3HT front cell limits the overall photocurrent, and hence the FF of tandem cells. A 10 nm layer of TiO₂:Cs was inserted between an Al cathode and PSBTBT:PC₇₀BM BHJ for efficient electron extraction (M.-H. Park, J.-H. Li, A. Kumar, G. Li, Y. Yang, Adv. Funct. Mater. 2009, 19, 1241).

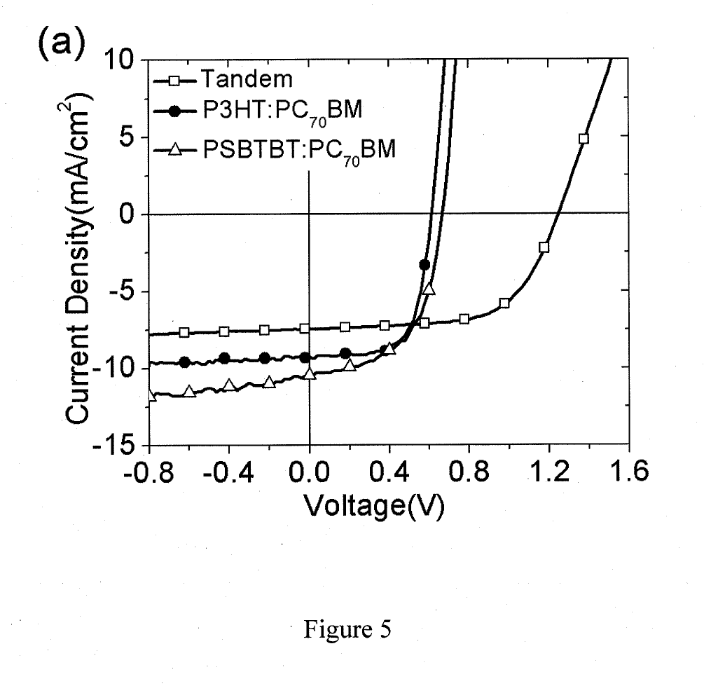

The current density vs. voltage (J-V) characteristics of the tandem and reference single cells were taken under AM1.5G 100 mW/cm² illumination as shown in FIG. 5 and photovoltaic parameters are listed in Table 1. The tandem cell yields a PCE of 5.84% with a V_{oc} of 1.25 V. From P3HT:PC₇₀BM BHJs with a thickness of 150 nm, PCE of 3.77% is obtained with J_{sc} of 9.27 mA/cm². The low bandgap PSBTBT:PC₇₀BM BHJ with a thickness of 100 nm exhibits J_{sc} of 10.71 mA/cm² and a PCE of 3.94%.

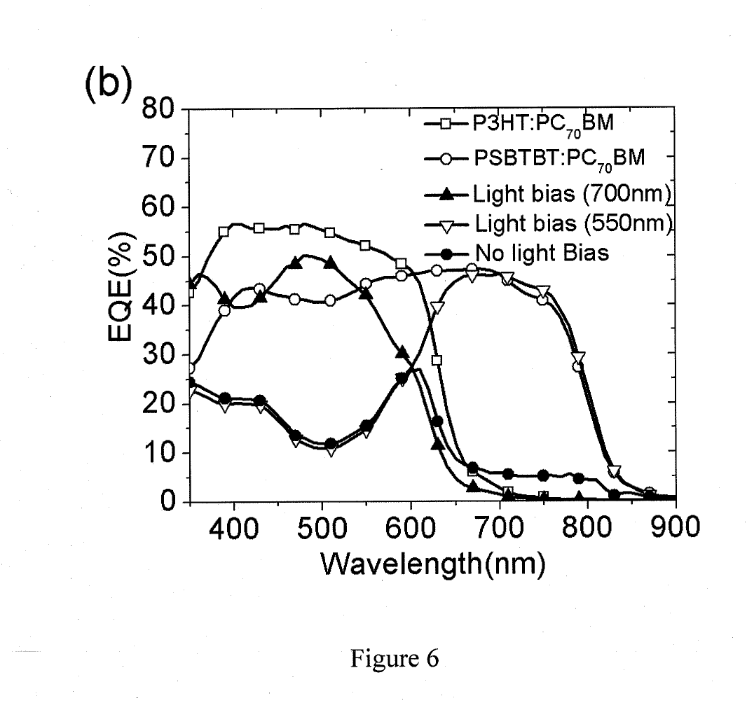

As shown in FIG. 6, the external quantum efficiency (EQE) of the tandem cell and single cells as reference was measured using the method proposed by Kim et al. However, it should be noted that EQE measurement using this method is appropriate only for the case in which the two sub-cells have shunt resistance large enough (see supporting information, SI-[C]). The EQE curve of the reference cell based on P3HT:PCBM has an average value over 50% throughout the visible range, due to strong absorption of both P3HT and PC₇₀BM. Photoresponse of the single PSBTBT:PC₇₀BM cell is consistent with our previously report (J. H. Hou, H.-Y. Chen, S. Zhang, G. Li, Y. Yang, J. Am. Chem. Soc. 2008, 130, 16144), showing a broad response range from 350 nm to 800 nm with a maximum over 40% at 700 nm. Integrating EQE curves under AM1.5G solar spectrum yields J_{sc} values consistent with the I-V curves shown in FIG. 5.

We modified the surface of the P3HT:PC₇₀BM film by depositing an ultrathin Al (UT-Al) layer, improving both the wettability and electrical contact of TiO₂ film on P3HT:PC₇₀BM film. The resulting TiO₂ film consists of a densely packed network of TiO₂ nanocrystals (see SI-[D], FIG. SI-3), which is able to prevent penetration of subsequently deposited layers, therefore, collecting electrons and blocking holes with a high selectivity. This is critical to preserve V_{oc} of tandem cells according to some embodiments of the current invention.

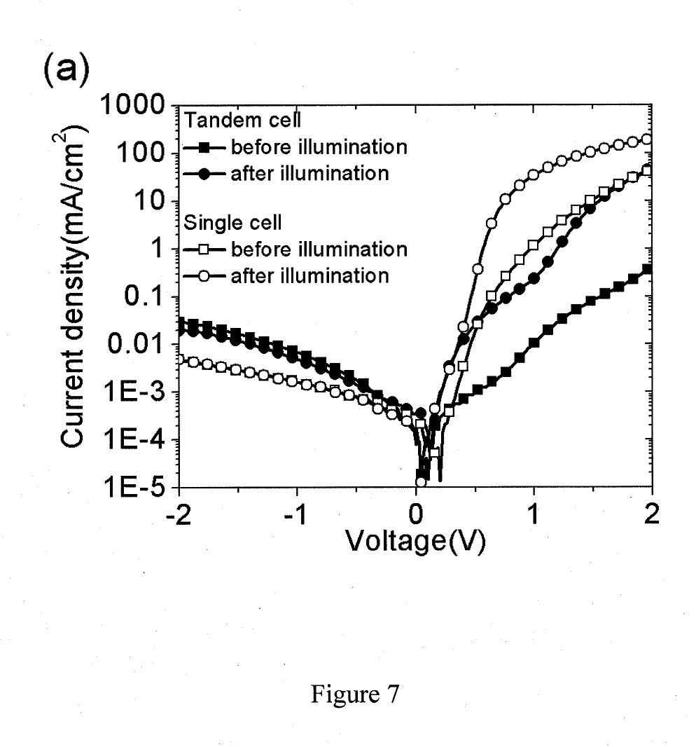

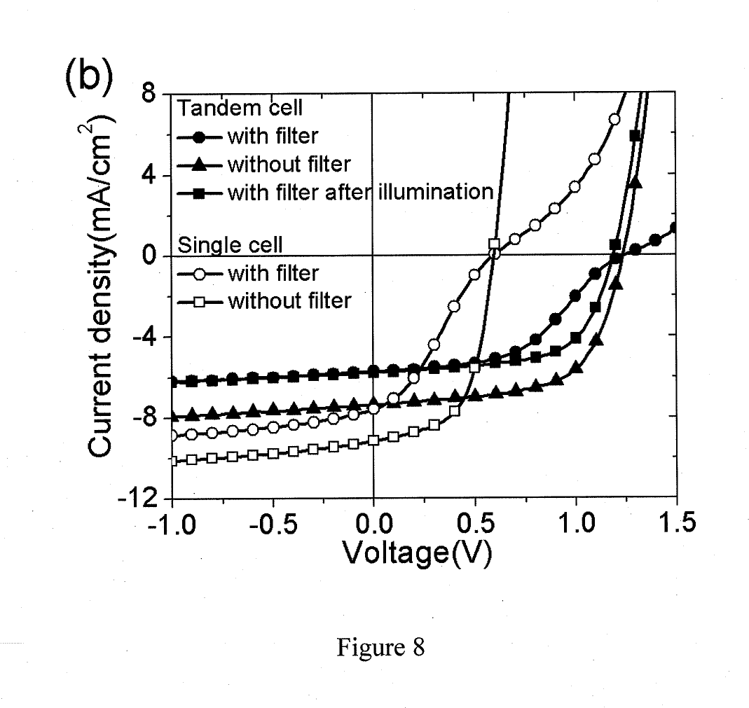

As listed in Table 1, V_{oc} of the tandem cell approaches the sum of the two reference cells, suggesting effectiveness of the interlayer. From the dark J-V curves of a fresh tandem cell shown in FIG. 7, we noted that the rectification ratio at ±2.0 V is only ˜10, though the tandem cells with such a poor diode behavior delivers a PCE of 5.84%. This rectification ratio improved by two orders of magnitude after illumination. The reason is tentatively attributed to the photoconductivity of TiO₂. To confirm this, the J-V characteristics under illumination with and without a 400 nm cutoff filter, that completely blocks UV part of solar spectrum, were measured and are shown in FIG. 8. When the device is illuminated without any UV photons, a significant hump, so-called “S-shape”, near V_{oc} was observed (A. Kumar, S. Sista, Y. Yang, J. Appl. Phys. Accepted). This S-shape should be related to an interfacial barrier for charge transport (C. Uhrich, R. Schueppel, A. Petrich, M. Pfeiffer, K. Leo, E. Brier, P. Kilickiran, P. Baeuerle, Adv. Funct. Mater. 2007, 17, 2991). Interestingly, when the cutoff filter is removed, the S-shape disappears and is not observed even though the cutoff filter is added again. This phenomenon is observed only when UV-light is cut-off, implying that TiO₂ is the origin, while this observation cannot be considered merely as photoconductivity (N. Golego, S. A. Studenikin, M. Cocivera, Phys. Rev. B 2000, 61, 8262).

TABLE 1
Photovoltaic performance of reference
single cells and a tandem cell.

| Device | PCE[%] | V_{oc}[V] | J_{sc}[mA/cm²] | FF[%] |
|---|---|---|---|---|
| P3HT:PC₇₀BM | 3.77 | 0.60 | 9.27 | 66.6 |
| PSBTBT:PC₇₀BM | 3.94 | 0.67 | 10.71 | 55.8 |
| Tandem | 5.84 | 1.25 | 7.44 | 63.2 |

A similar phenomenon is observed for a P3HT:PC₇₀BM single cell with UT-Al/TiO₂/PEDOT4083/Al as the cathode as shown in FIGS. 7 and 8. It can be seen that inserting PEDOT4083 between TiO₂ layer and Al cathode have negligible influence on J-V characteristics. Considering Ohmic contact between Al and PEDOT4083, there appeared a UV-induced Schottky-to-Ohmic transition of PEDOT4083/TiO₂ contact. TiO₂ has an electron quasi-Fermi level near to the LUMO level of PCBM, and on the other hand, PEDOT4083 is a heavily p-doped conductive polymer, which can be regarded as a high work function metal. Therefore, TiO₂/PEDOT4083 can be considered as a metal-semiconductor contact that forms a triangular barrier as shown in FIG. 2. In case of a large width of triangular barrier due to small carrier concentration in TiO₂ upon Fermi level alignment, both extraction and injection of electrons were blocked, resulting in the S-shape in absence of UV light. Upon shining UV light, the free carrier concentration in TiO₂ significantly increases, leading to narrowing of the triangular barrier width that is thin enough for efficient tunneling of electrons through the triangular barrier. This is equivalent to having no energy barrier across the TiO₂/PEDOT4083 interface, which explains the observed increase in the forward bias current by 2 orders of magnitude upon exposure to UV light. Unfortunately, the carrier density and the conductivity of TiO₂ nanocrystal is difficult to characterize quantitatively.

Therefore, the nature of the interlayer for our polymer tandem cells is established to behave as a metal-semiconductor junction, i.e. a Schottky contact. The contact properties of TiO₂/PEDOT4083 are believed to be determined by photogenerated electrons in TiO₂ layer induced by UV light. Unlike the highly doped p-n junction for carrier tunneling without any potential loss in inorganic tandem cells (J. M. Olson, S. R. Kurtz, A. E. Kibbler, P. Faine, Appl. Phys. Lett. 1990, 56, 623), the TiO₂/PEDOT4083 interface in the single cell of ITO/PEDOT4083/P3HT:PC₇₀BM/UT-Al/TiO₂/PEDOT4083/Al showed a normal diode behavior with a significant rectification as shown from dark J-V curve in FIG. 7, because the n-type TiO₂ layer transports electrons only, and a hole injection into TiO₂ is energetically forbidden.

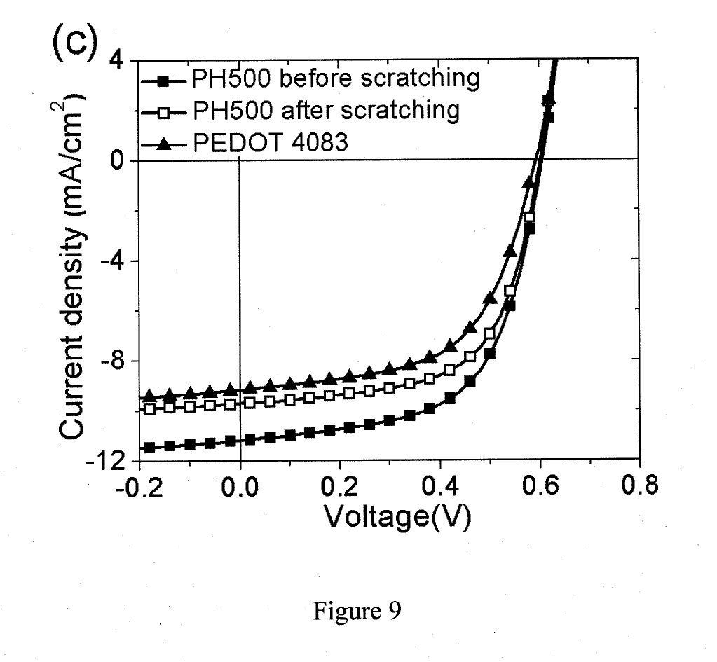

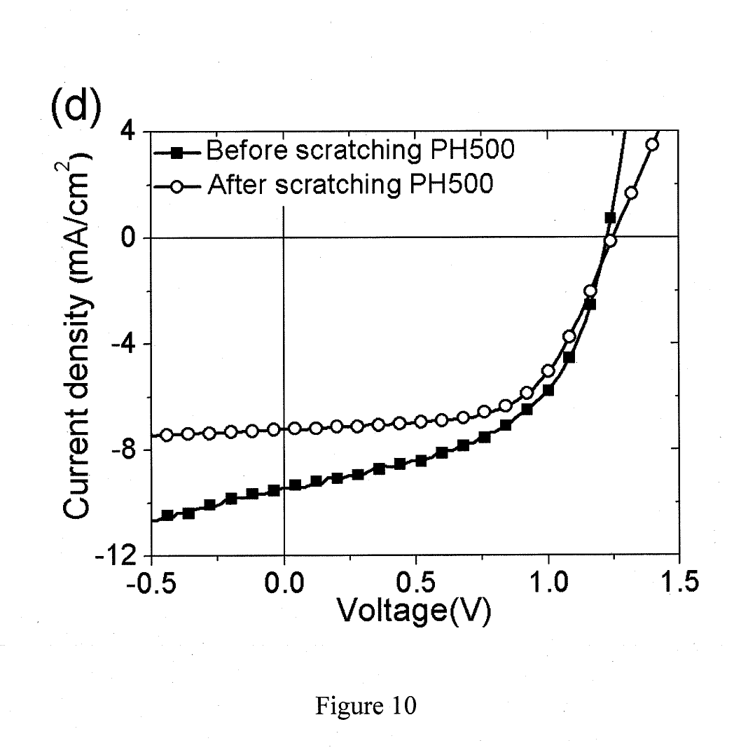

Another important concern that should be addressed is the effect of conductivity of the PEDOT:PSS layer on the active area of the device. FIG. 9 shows the J-V characteristics under light illumination of devices, ITO/PEDOT4083/P3HT:PC₇₀BM/UT-Al/TiO₂/PEDOT:PSS/Al. When PH500 is used for a second PEDOT:PSS layer, J_{sc} increases to 11.2 mA/cm², which is nearly 20% higher than the J_{sc} of the control device with PEDOT4083, while no difference of EQE for two cells was observed. The increased J_{sc} is ascribed to the high conductivity of PH500 films, 5˜10 Scm⁻¹, which causes the larger active area than the electrode overlap. We defined the active area of by scratching the PH500 layer along the edge of Al cathode, and the J_{sc} was reduced to 9.5 mA/cm². The tandem cell using PH500 as an interlayer reaches PCE of 6.01%, however, after redefining the effective area, the efficiency also drops to 5.44% as shown in FIG. 10. J_{sc} over 9 mA/cm² of the tandem cell, which is ˜20% higher than J_{sc} obtained by EQE, supports that PH500 layer increases the active area for front cell (A. Cravino, P. Schilinsky, C. J. Brabec, Adv. Funct. Mater. 2007, 17, 3906). In this case, the rear sub-cell becomes the photocurrent limiting cell giving low FF of 55% for tandem cells (A. Hadipour, B. de Boer, P. W. M. Blom, Org. Elect. 2008, 9, 617). After scratching, the front cell limits the overall photocurrent, resulting in FF higher than 60%. According to our observation, extra care over efficiency estimation has to be taken when using highly conductive materials in the interlayer.

In summary, we demonstrate an efficient photovoltaic cell with a tandem structure according to some embodiments of the current invention. Studies of the mechanism indicates that a metal/semiconductor contact formed between conductive polymer and semiconducting metal oxide, which connects individual sub-cells in series, works effectively as the interlayer. It is worth pointing out that the front cell with larger bandgap should offer higher V_{oc} to exploit the full potential of the tandem cells (G. Dennler, M. C. Scharber, T. Ameri, P. Denk, K. Forberich, C. Waldauf, C. J. Brabec, Adv. Mater. 2008, 20, 579). In this sense, P3HT is used mainly to demonstrate the concept, rather than efficiency improvement, because the large bandgap of P3HT offers a mediocre V_{oc} of 0.6 V. With suitable combination of donor-acceptor systems, that are able to deliver higher V. from front cell (R. B. Ross, C. M. Cardona, D. M. Guldi, S. G. Sankaranarayanan, M. O. Reese, N. Kopidakis, J. Peet, B. Walker, G. C. Bazan, E. Van Keuren, B. C. Holloway, M. Drees, Nat. Mater. 2009, 8, 208), all other parameters remaining the same as for P3HT, PCE of tandem cells can be significantly improved over the particular examples shown here. The broad concepts of the current invention are not limited to these particular examples.

### Experimental

Device Fabrication: Photovoltaic cells were fabricated on indium tin oxide (ITO) coated glass substrates with a sheet resistance of 15 Ω/□. The PEDOT:PSS layer was spin-casted at 4000 rpm for 60 sec, and annealed at 140° C. for 15 min. The P3HT:PC₇₀BM at a 1:0.7 weight ratio in 1% chloroform solution was spin-casted at 4000 rpm for 30 sec on top of a layer of PEDOT 4083. The films were annealed at 150° C. for 30 min. After thermal evaporation of 5 Å Al in vacuum, a thin layer of n-type nanocrystalline TiO₂ film was spin-casted from 0.25 wt. % of TiO₂ solution in a 1:1 volume ratio of 2-ethoxyethanol and ethanol at 1000 rpm, followed by thermal annealing at 120° C. for 10 min. After spin-coating of second PEDOT:PSS layer, PSBTBT:PC₇₀BM (1:1.5) from 1% chloroform solution was drop-cased while the substrate was spinning at 4500 rpm and another thermal annealing step was performed at 140° C. for 5 min. Finally, a TiO₂:Cs solution prepared by blending 0.5 & 0.2 wt. % solutions of TiO₂ & Cs₂CO₃ in 1:1 volume ratio was spin-casted at 3000 rpm for 30 s, and the thermal annealing was performed at 80° C. for 20 min. The device fabrication was completed by thermal evaporation of 80 nm Al as the cathode under vacuum at a base pressure of 2×10⁻⁶ torr.

Electrical, optical and microscopic characterization of photovoltaic cells and thin films: The absorption spectra were taken using a Varian Cary 50 ultraviolet-visible spectrophotometer. The n and k values for the different layers in the tandem cell were measured using ellipsometer and the values obtained were fed into the software to get the optical field profile. Current-voltage characteristics of photovoltaic cells were taken using a Keithley 4200 source unit under stimulated AM1.5G spectrum with an Oriel 9600 solar simulator. AFM images were taken on digital instruments multimode scanning probe microscope. For EQE and XPS/UPS measurements, refer to SI-[C] and [D], respectively.

The current invention was described with reference to particular embodiments and examples. However, this invention is not limited to only the embodiments and examples described. One of ordinary skill in the art should recognize, based on the teachings herein, that numerous modifications and substitutions can be made without departing from the scope of the invention which is defined by the claims.

We claim:

1. A tandem polymer photovoltaic device, comprising:
a first bulk hetero junction polymer semiconductor layer;
a second bulk hetero junction polymer semiconductor layer spaced apart from said first bulk hetero-junction polymer semiconductor layer; and
a metal-semiconductor layer between and in contact with said first and second bulk hetero-junction polymer semiconductor layers,
wherein said first and second bulk hetero junction polymer semiconductor layers have complementary photon absorption spectra.

2. A tandem polymer photovoltaic device according to claim 1, wherein said metal-semiconductor layer comprises an n-type sub-layer and a p-type sub-layer.

3. A tandem polymer photovoltaic device according to claim 2, wherein said n-type sub-layer of said metal-semiconductor layer comprises nano-crystalline TiO₂.

4. A tandem polymer photovoltaic device according to claim 3, wherein said p-type sub-layer of said metal-semiconductor layer comprises PEDOT:PSS.

5. A tandem polymer photovoltaic device according to claim 2, wherein said metal-semiconductor layer further comprises a wetting layer between said n-type sub-layer and one of said first and second bulk hetero-junction polymer semiconductor layers.

6. A tandem polymer photovoltaic device according to claim 4, wherein said metal-semiconductor layer further comprises a wetting layer of aluminum between said n-type sub-layer and one of said first and second bulk hetero-junction polymer semiconductor layers.

7. A tandem polymer photovoltaic device according to claim 6, wherein said wetting layer of aluminum is less than 1 nm thick.

8. A tandem polymer photovoltaic device according to claim 7, wherein said first bulk hetero-junction polymer semiconductor layer consists essentially of P3HT:PC₇₀BM and said second bulk hetero-junction polymer semiconductor layer consists essentially of PSBTBT:PC₇₀BM.

9. A tandem polymer photovoltaic device according to claim 8, further comprising a transparent electrode on a transparent substrate in electrical connection with said first bulk hetero junction polymer semiconductor layer and a metal electrode in electrical connection with said second bulk hetero junction polymer semiconductor layer.

10. A tandem polymer photovoltaic device according to claim 9, further comprising an electron extraction layer between said second bulk hetero-junction polymer semiconductor layer and said metal electrode.

11. A method of producing a tandem polymer photovoltaic device, comprising:
providing a transparent substrate structure comprising a transparent substrate and a transparent electrode;
forming a first bulk hetero-junction polymer semiconductor layer in electrical connection with said transparent electrode;
forming a metal-semiconductor layer in electrical connection with said first bulk hetero-junction polymer semiconductor layer; and
forming a second bulk hetero junction polymer semiconductor layer in electrical connection with said metal-semiconductor layer,
wherein said first and second bulk hetero-junction polymer semiconductor layers have complementary photon absorption spectra.

12. A method of producing a tandem polymer photovoltaic device according to claim 11, wherein said metal-semiconductor layer comprises an n-type sub-layer and a p-type sub-layer.

13. A method of producing a tandem polymer photovoltaic device according to claim 11, wherein said forming said metal-semiconductor layer comprises forming an n-type sub-layer of nano-crystalline TiO₂ by a non-hydrolytic sol-gel process.

14. A method of producing a tandem polymer photovoltaic device according to claim 12, wherein said p-type sub-layer of said metal-semiconductor layer comprises PEDOT:PSS.

15. A method of producing a tandem polymer photovoltaic device according to claim 12, wherein said metal-semiconductor layer further comprises a wetting layer of aluminum between said n-type sub-layer and one of said first and second bulk hetero-junction polymer semiconductor layers.

16. A method of producing a tandem polymer photovoltaic device according to claim 15, wherein said wetting layer of aluminum is less than 1 nm thick.

17. A method of producing a tandem polymer photovoltaic device according to claim 16, wherein said first bulk hetero-junction polymer semiconductor layer consists essentially of P3HT:PC₇₀BM and said second bulk hetero junction polymer semiconductor layer consists essentially of PSBTBT:PC₇₀BM.
